(19) United States
(12) Patent Application Publication
(10) Pub. No.: US 2025/0298734 A1
(43) Pub. Date: Sep. 25, 2025

(54) DIFFERENTIAL COMPUTATION CIRCUIT AND MEMORY DEVICE INCLUDING THEREOF, AND OPERATION METHOD OF THE MEMORY DEVICE

(71) Applicant: Samsung Electronics Co., Ltd., Suwon-si (KR)

(72) Inventor: Ho-Youn KIM, Suwon-si (KR)

(73) Assignee: Samsung Electronics Co., Ltd., Suwon-si (KR)

(21) Appl. No.: 18/828,414

(22) Filed: Sep. 9, 2024

(30) Foreign Application Priority Data
Mar. 21, 2024 (KR) 10-2024-0039288

(51) Int. Cl. G06F 12/02; G11C 8/10

(52) U.S. Cl. CPC G06F 12/0223; G11C 8/10

(57) ABSTRACT

A memory device according various example embodiments may comprise a format conversion circuit configured to generate a plurality of differential weights based on a plurality of weights provided from an external device, a memory cell array configured to store a first input element provided from the external device and the plurality of differential weights, a quantization circuit configured to generate a plurality of scale coefficients based on the plurality of differential weights, and an input element scaling circuit configured to provide a plurality of output elements corresponding to products of the first input element and each of the plurality of weights to the external device based on the plurality of scale coefficients.

### CROSS-REFERENCE TO RELATED APPLICATION

This application claims priority to and the benefit of Korean Patent Application No. 10-2024-0039288 filed at the Korean Intellectual Property Office on Mar. 21, 2024, the entire contents of which are incorporated herein by reference.

### BACKGROUND

Various example embodiments relate to a semiconductor memory device. More specifically, various example embodiments relate to a differential computation circuit performing multiplication computation and/or a memory device including thereof.

As an artificial intelligence technology has recently developed, an amount of computation required to operate an artificial intelligence model is rapidly increasing. However, in general, an amount of computation that may be processed by devices such as one or more of a smartphone, a personal computer, or the like may be insufficient to normally drive the artificial intelligence model. Accordingly, various methods for operating the artificial intelligence model with a smaller amount of computation are being researched.

In general, an operation speed of a memory device and an operation speed of a processor are faster than a communication speed between the processor and the memory device. In this case, a bottleneck phenomenon may occur in an operation of the memory device and a computation of the processor due to the communication speed between the processor and the memory device. Particularly, if the artificial intelligence model is operated by the processor and the memory device, an operation speed of the artificial intelligence model may be deteriorated by the bottleneck phenomenon. Accordingly, various technologies are being researched to solve or improve upon the bottleneck phenomenon caused by the communication speed. For example, a processing-in-memory (PIM) technology in which the memory device performs some computation operations has recently been researched.

### SUMMARY

Various example embodiments may solve or improve upon the above-described technical problem. More specifically, various example embodiments may provide a differential computation circuit performing a computation operation in a more simplified form, and/or a memory device including thereof.

A memory device according to some example embodiments comprises a format conversion circuit configured to generate a plurality of differential weights based on a plurality of weights provided from an external device, a memory cell array configured to store a first input element provided from the external device and to store the plurality of differential weights, a quantization circuit configured to generate a plurality of scale coefficients based on the plurality of differential weights, and an input element scaling circuit configured to provide a plurality of output elements corresponding to products of the first input element and each of the plurality of weights to the external device based on the plurality of scale coefficients.

Alternatively or additionally a differential computation circuit included in an internal processor of a memory device according to various example embodiments includes a quantization circuit configured to generate 0-th to n-th scale coefficients based on 0-th to n-th differential weights (wherein n is an integer greater than or equal to 1), and an input element scaling circuit configured to generate 0-th to n-th output elements based on the 0-th to n-th scale coefficients and on an input element. the input element scaling circuit comprises a power scaling circuit configured to generate 0-th to n-th differentially scaled input elements by scaling the input element based on the 0-th to n-th scale coefficients, and an accumulation circuit configured to sequentially generate the 0-th to n-th output elements by sequentially accumulating the 0-th to n-th differentially scaled input elements.

Alternatively or additionally an operation method of a memory device according to various example embodiments includes storing 0-th and first differential weights generated based on 0-th and first weights provided from an external device, receiving a first input element from the external device, receiving a weight multiplication command for the 0-th and first weights and the first input element from the external device, generating, based on 0-th and first differentially scaled input elements respectively corresponding to products of the first input element with the 0-th and first differential weights, 0-th and first output elements respectively corresponding to products of the first input element and the 0-th and first weights, in response to the weight multiplication command, and outputting the 0-th and first output elements to the external device.

### BRIEF DESCRIPTION OF THE DRAWINGS

FIG. 1 is a block diagram showing a memory system according to various example embodiments.

FIG. 2 is a block diagram showing a memory device of FIG. 1 in more detail.

FIG. 3 is a block diagram showing a configuration of an internal processor of FIG. 2.

FIG. 4 is a drawing showing an operation of a format conversion circuit of FIG. 3 in more detail.

FIG. 5 is a drawing showing a configuration and an operation of a differential computation circuit of FIG. 3 in more detail.

FIG. 6 is a drawing showing an operation of a quantization circuit of FIG. 5 according to various example embodiments in more detail.

FIG. 7 is a drawing showing an operation of the quantization circuit of FIG. 5 according to various example embodiments in more detail.

FIG. 8 is a drawing showing an operation of the quantization circuit of FIG. 5 according to various example embodiments in more detail.

FIG. 9 is a drawing showing an operation of the quantization circuit of FIG. 5 according to an embodiment in more detail.

FIG. 10 is a drawing showing a configuration and an operation of an input element scaling circuit of FIG. 5 in more detail.

FIG. 11 is a drawing showing an operation of a power scaling circuit of FIG. 10 in more detail.

FIG. 12 is a flowchart showing an operation method of the memory device according to various example embodiments.

FIG. 13 is a flowchart showing an operation S120 of FIG. 12 in more detail.

FIG. 14 is a flowchart showing an operation method of the memory device according to various example embodiments.

FIG. 15 is a flowchart showing an operation S230 of FIG. 14 in more detail.

FIG. 16 is a drawing showing a configuration and an operation of a control logic circuit of FIG. 2 according to various example embodiments.

### DETAILED DESCRIPTION

Below, various example embodiments will be described clearly and in detail to such an extent that a person of an ordinary skill in the technical field of the present disclosure may easily perform the present disclosure. Details such as detailed configurations and structures are provided simply to facilitate an overall understanding of example embodiments. Therefore, modifications of the example embodiments described herein may be performed by a person of an ordinary skill in the art without departing from the technical spirit and scope of the present disclosure. Moreover, descriptions of well-known functions and structures may be omitted for clarity and brevity. Configurations in the drawings or a detailed description of the present disclosure may be connected to an element other than that shown in the drawings or described in the detailed description. Terms used herein are defined considering functions of example embodiments, and are not limited to specific functions. The definition of the terms may be determined based on details described in the detailed description.

Elements described with reference to a term such as a driver, a block, or the like used in the detailed description may be implemented in the form of software, hardware, or a combination thereof. For example, the software may be a machine code, firmware, an embedded code, and application software. For example, the hardware may include an electrical circuit, an electronic circuit, a processor, a computer, integrated circuit cores, a pressure sensor, an inertial sensor, a microelectromechanical System (MEMS), a passive element, or a combination thereof.

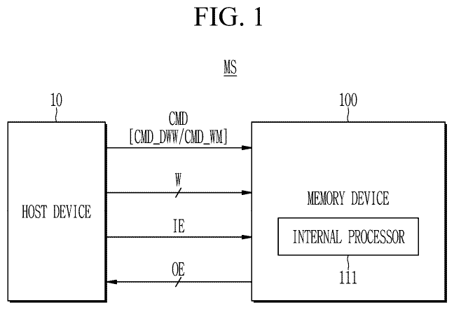

FIG. 1 is a block diagram showing a memory system according to various example embodiments. Referring to FIG. 1, the memory system MS may include a host device 10 and a memory device 100. The memory device 100 may include an internal processor 111.

In an embodiment, the host device 10 may be or may include one or more of various types of processors such as a central processing unit (CPU), a graphics processing unit (GPU), and the like.

For a more concise description, hereinafter, it is assumed that the memory device 100 is or includes a dynamic random access memory (DRAM) device and the host device 10 and the memory device 100 communicate with each other based on a low power double data rate (LPDDR) interface. However, the scope of inventive concepts are not limited thereto. For example, alternatively or additionally the host device 10 and the memory device 100 may communicate with each other based on a double data rate (DDR) interface.

The host device 10 may store data in the memory device 100, and/or may read data from the memory device 100. For example, the host device 10 may control an operation of the memory device 100 by transmitting a command CMD to the memory device 100.

The memory device 100 may perform various computation operations in response to a control of the host device 10. For example, the internal processor 111 may perform various computation operations based on the command CMD provided from the host device 10. Hereinafter, operations of the memory device 100 based on the internal processor 111 will be exemplarily described.

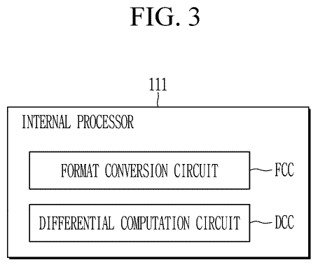

The host device 10 may write a plurality of weights W in the memory device 100, each in the same or in a differential format. For example, the host device 10 may transmit the plurality of weights W and a differential weight write command CMD_DWW to the memory device 100. In this case, the memory device 100 may convert the plurality of weights W into the differential format by using the internal processor 111. Thereafter, the memory device 100 may store the plurality of weights W converted into the differential format. A detailed method in which the internal processor 111 converts the plurality of weights W into the differential format will be described in more detail with reference to FIGS. 3 to 5 below.

The host device 10 may write an input element IE in the memory device 100. For example, the host device 10 may transmit an input element write command to the memory device 100. In this case, the memory device 100 may store the input element IE.

The host device 10 may request results obtained by multiplying the input element IE by each of the plurality of weights W to the memory device 100. For example, the host device 10 may provide a weight multiplication command CMD_WM to the memory device 100. In this case, based on the plurality of weights W converted into the differential format, the memory device 100 may compute a plurality of output elements OE corresponding to the results obtained by multiplying the input element IE by each of the plurality of weights W through the internal processor 111. Thereafter, the memory device 100 may provide the computed plurality of output elements OE to the host device 10.

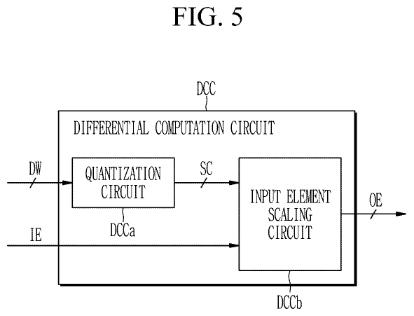

In various example embodiments, if the internal processor 111 computes the plurality of output elements OE based on the plurality of weights W of differential format, then there may be a reduction in an amount of computation of the internal processor 111 compared with a case where the internal processor 111 computes the plurality of output elements OE by directly multiplying the input element IE by each of the plurality of weights W. For example, according to some example embodiments, the internal processor 111 may compute the plurality of output elements OE corresponding to the results obtained by multiplying the input element IE by each of the plurality of weights W with a reduced or a minimized amount of computation. A detailed method in which the internal processor 111 computes the plurality of output elements OE will be described in more detail with reference to FIGS. 5 to 11 below.

In various example embodiments, a case where the memory device 100 (for example, the internal processor 111) directly computes the plurality of output elements OE may reduce an amount of computation processed by the host device 10 as compared with a case where the host device 10 computes the plurality of output elements OE.

In various example embodiments, if the memory device 100 directly computes the plurality of output elements OE, the host device 10 may immediately or more immediately receive the plurality of output elements OE from the memory device 100 even if the host device 10 does not read the plurality of weights W and the input element IE. Therefore, according to some example embodiments, data exchange between the host device 10 and the memory device 100 may be reduced or minimized, so that a bottleneck phenomenon in operations of the host device 10 and the memory device 100 caused by communication between the host device 10 and the memory device 100 may be reduced or minimized.

Because the bottleneck is reduced or minimized, data that is output by the plurality of output elements OE may be used or more useful as inputs or during applications utilizing artificial intelligence (AI), for example for AI applications including one or more of large-language model (LLM) calculations and/or diffusion-based calculations. By reducing the bottleneck in providing a plurality of output elements OE for such applications, the AI applications may be run faster, and/or may be run with reduced power consumption.

In various example embodiments, the memory system MS may be included in one or more of various types of electronic devices such as one or more of a smartphone, a laptop computer, a personal computer, a tablet PC, and the like, and/or in systems including one or more of the above. In this case, the memory system MS may be used for an operation of an on-device artificial intelligence model driven in the electronic device. However, example embodiments are not limited thereto.

In various example embodiments, the host device 10 may provide the command CMD to the memory device 100 based on a plurality of command/address pins. However, the scope of the present disclosure is not limited to a specific manner in which the host device 10 provides the command CMD to the memory device 100.

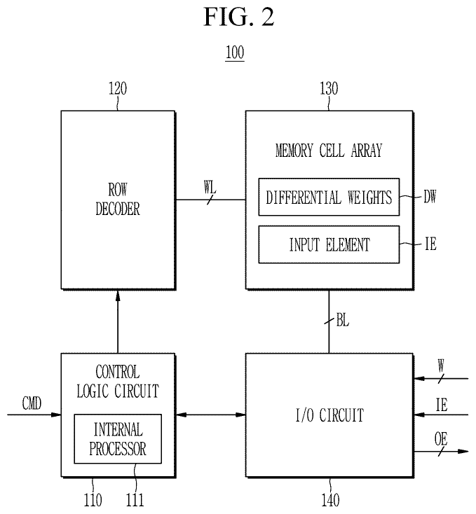

FIG. 2 is a block diagram showing the memory device of FIG. 1 in more detail. Referring to FIG. 2, the memory device 100 may include a control logic circuit 110, a row decoder 120, a memory cell array 130, and an input/output circuit 140. Each of the control logic circuit 110, the row decoder 120, the memory cell array 130, and the input/output circuit 140 may communicate to others of the control logic circuit 110, the row decoder 120, the memory cell array 130, and the input/output circuit 140 as shown and/or in other manners such as in one-way and/or two-way and/or broadcast manner; example embodiments are not limited thereto.

The control logic circuit 110 may receive the command CMD. The control logic circuit 110 may control an overall operation of the memory device 100 based on the command CMD. For example, the control logic circuit 110 may control operations of the row decoder 120 and/or of the input/output circuit 140.

The row decoder 120 may control a plurality of word lines WL in response to a control of the control logic circuit 110. For example, the row decoder 120 may activate some of the plurality of word lines WL in response to the control of the control logic circuit 110.

The memory cell array 130 may include a plurality of memory cells disposed in a matrix fashion, e.g., in a row direction and a column direction. The plurality of memory cells may be connected to the plurality of word lines WL extending in the row direction and a plurality of bit lines BL extending in the column direction.

The input/output circuit 140 may receive data from the host device 10, or may transmit data to the host device 10. For example, the input/output circuit 140 may receive the plurality of weights W and the input element IE from the host device 10, and may provide the plurality of output elements OE to the host device 10.

The input/output circuit 140 may be connected to the memory cell array 130 through the plurality of bit lines BL. The input/output circuit 140 may control the plurality of bit lines BL to read data stored in the memory cell array 130 or store data in the memory cell array 130.

When a write command for the input element IE is provided to the control logic circuit 110, the control logic circuit 110 may control the row decoder 120 and the input/output circuit 140 to store the input element IE in the memory cell array 130.

The control logic circuit 110 may include the internal processor 111. The internal processor 111 may perform various computation operations.

When the differential weight write command CMD_DWW is provided to the control logic circuit 110, the internal processor 111 may convert the plurality of weights W provided from the host device 10 into the differential format. Thereafter, the control logic circuit 110 may control the row decoder 120 and the input/output circuit 140 to store the plurality of weights W converted to the differential format (hereinafter it will be referred to as a plurality of differential weights DW).

In various example embodiments, if the differential weight write command CMD_DWW is provided to the control logic circuit 110, the control logic circuit 110 may store the plurality of differential weights DW in the memory cell array 130. For example, the control logic circuit 110 may respond to the differential weight write command CMD_DWW to store the plurality of differential weights DW instead of the plurality of weights W in the memory cell array 130. However, example embodiments are not limited thereto, and the control logic circuit 110 may store both the plurality of weights W and the plurality of differential weights DW in the memory cell array 130 in response to the differential weight write command CMD_DWW.

When the weight multiplication command CMD_WM is provided to the control logic circuit 110, the control logic circuit 110 may control the row decoder 120 and the input/output circuit 140 to provide the input elements IE and the plurality of differential weights DW stored in the memory cell array 130 to the internal processor 111. In this case, the internal processor 111 may compute the plurality of output elements OE based on the input element IE and the plurality of differential weights DW. Thereafter, the control logic circuit 110 may provide the plurality of output elements OE to the host device 10 through the input/output circuit 140. A detailed method in which the internal processor 111 computes the plurality of output elements OE will be described in more detail with reference to FIGS. 5 to 11 below.

FIG. 3 is a block diagram showing a configuration of the internal processor of FIG. 2. Referring to FIGS. 1 to 3, the internal processor 111 may include a format conversion circuit FCC and a differential computation circuit DCC.

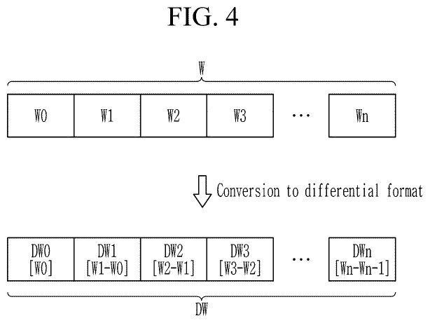

The format conversion circuit FCC may convert the plurality of weights W to the differential format. For example, the format conversion circuit FCC may generate the plurality of differential weights DW based on the plurality of weights W. An operation of the format conversion circuit FCC will be described in more detail with reference to FIG. 4 below.

The differential computation circuit DCC may generate the plurality of output elements OE based on the plurality of differential weights DW and the input element IE. In this case, the plurality of output elements OE may correspond to products of the plurality of differential weights DW and the input element IE, respectively. A configuration and an operation of the differential computation circuit DCC will be described in more detail with reference to FIGS. 5 to 11.

The format conversion circuit FCC may communicate with the differential computation circuit DCC in one or more of a one-way manner, a two-way manner, or a broadcast manner, and may send and/or receive data such a serial data and/or parallel data in analog format and/or in digital format; example embodiments are not limited thereto.

FIG. 4 is a drawing showing an operation of the format conversion circuit of FIG. 3 in more detail. Referring to FIGS. 1 to 4, the format conversion circuit FCC may convert the plurality of weights W to the differential format. That is, the format conversion circuit FCC may generate the plurality of differential weights DW based on the plurality of weights W. For a more concise description, hereinafter, various example embodiments in which the format conversion circuit FCC generates 0-th to n-th differential weights DW0-DWn based on 0-th to n-th weights W0-Wn will be representatively described.

The format conversion circuit FCC may receive the 0-th to n-th weights W0-Wn.

The format conversion circuit FCC may generate the 0-th differential weight DW0 corresponding to the 0-th weight W0 based on the 0-th weight W0. For example, the 0-th differential weight DW0 may be same as the 0-th weight W0.

The format conversion circuit FCC may generate the first to n-th differential weights DW1-DWn based on a difference between each of the first to n-th weights W1-Wn and on a weight preceding each of the first to n-th weights W1-Wn. In other words, the format conversion circuit FCC may generate the k-th differential weight DWk based on the difference between the k-th weight Wk and the (k-1)-th weight Wk-1 (wherein ‘k’ is an integer equal to or greater than 1 and equal to or less than n). For example, the format conversion circuit FCC may generate the first differential weight DW1 based on the difference between the first weight W1 and the 0-th weight W0, and may generate the second differential weight DW2 based on the difference between the second weight W2 and the first weight W1. In a similar manner, the format conversion circuit FCC may also generate the third to n-th differential weights DW3-DWn.

In various example embodiments, the 0-th weight W0 may be referred to as an initial weight. The initial weight may be the most preceding weight from among the plurality of weights W provided to the memory device 100.

In various example embodiments, each of the 0-th to n-th weights W0-Wn may have a floating-point data type. For example, each of the 0-th to n-th weights W0-Wn may include a sign part, an exponent part, and a mantissa part.

In various example embodiments, if each of the 0-th to n-th weights W0-Wn has an FP32 data type, a code length of the exponent part of each of the 0-th to n-th weights W0-Wn may be 8 bits, and a code length of the mantissa part of each of the 0-th to n-th weights W0-Wn may be 23 bits.

In various example embodiments, if each of the 0-th to n-th weights W0-Wn has an FP16 data type, a code length of the exponent part of each of the 0-th to n-th weights W0-Wn may be 5 bits, and a code length of the mantissa part of each of the 0-th to n-th weights W0-Wn may be 10 bits.

In various example embodiments, each of the 0-th to n-th differential weights DW0-DWn may have a floating-point data type. That is, each of the 0-th to n-th differential weights DW0-DWn may have the same data type as that of each of the 0-th to n-th weights W0-Wn.

In various example embodiments, the 0-th differential weight DW0 may be referred to as an initial differential weight. The initial differential weight may be the same as the initial weight.

In various example embodiments, the control logic circuit 110 may store the 0-th to n-th differential weights DW0-DWn computed by the format conversion circuit FCC in the memory cell array 130.

In various example embodiments, if a read request for the 0-th to n-th weights W0-Wn is received from the host device 10, the control logic circuit 110 may compute the 0-th to n-th weights W0-Wn based on the 0-th to n-th differential weights DW0-DWn through the internal processor 111. For example, the control logic circuit 110 may compute the first weight W1 by summing the 0-th weight W0 and the first differential weight DW1, and may compute the second weight W2 by summing the first weight W1 and the second differential weight DW2. In this way, the control logic circuit 110 may sequentially compute the 0-th to n-th weights W0-Wn based on the 0-th to n-th differential weights DW0-DWn to provide the computed weights to the host device 10. However, example embodiments are not limited thereto.

FIG. 5 is a drawing showing a configuration and an operation of the differential computation circuit of FIG. 3 in more detail. Referring to FIGS. 1 to 5, in some example embodiments the differential computation circuit DCC may include a quantization circuit DCCa and an input element scaling circuit DCCb.

The quantization circuit DCCa may receive the plurality of differential weights DW. For example, the quantization circuit DCCa may receive the 0-th to n-th differential weights DW0-DWn stored in the memory cell array 130.

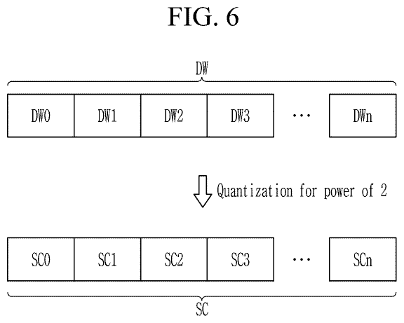

The quantization circuit DCCa may generate a plurality of scale coefficients SC based on the plurality of differential weights DW. For example, the quantization circuit DCCa may generate 0-th to n-th scale coefficients SC0-SCn by quantizing the 0-th to n-th differential weights DW0-DWn, respectively. A more detailed operation of the quantization circuit DCCa will be described in more detail with reference to FIGS. 6 to 9 below.

In various example embodiments, the 0-th to n-th scale coefficients SC0-SCn may have an integer data type. In this case, a code length of each of the 0-th to n-th scale coefficients SC0-SCn may be small compared with a code length of each of the 0-th to n-th differential weights DW0-DWn.

In various example embodiments, the scale coefficient generated based on the initial differential weight (e.g., the 0-th scale coefficient SC0) may be referred to as an initial scale coefficient.

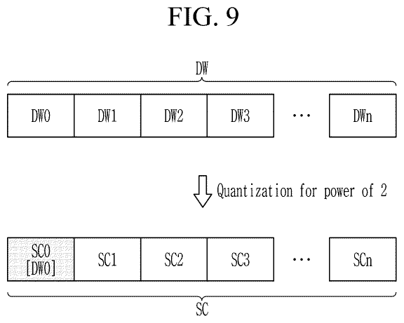

In some example embodiments, the quantization circuit DCCa may not quantize the initial differential weight among the plurality of differential weights DW. For example, the quantization circuit DCCa may generate the first to n-th scale coefficients SC1-SCn by quantizing the first to n-th differential weights DW1-DWn, respectively, and may not quantize the 0-th differential weight DW0. In this case, the initial differential weight may be equal to the initial scale coefficient. Various example embodiments in which the quantization circuit DCCa does not quantize the initial differential weight will be described in more detail with reference to FIG. 9 below.

The input element scaling circuit DCCb may receive the input element IE. For example, the input element scaling circuit DCCb may receive the input element IE stored in the memory cell array 130.

The input element scaling circuit DCCb may receive the plurality of scale coefficients SC. For example, the input element scaling circuit DCCb may receive the 0-th to n-th scale coefficients SC0-SCn from the quantization circuit DCCa.

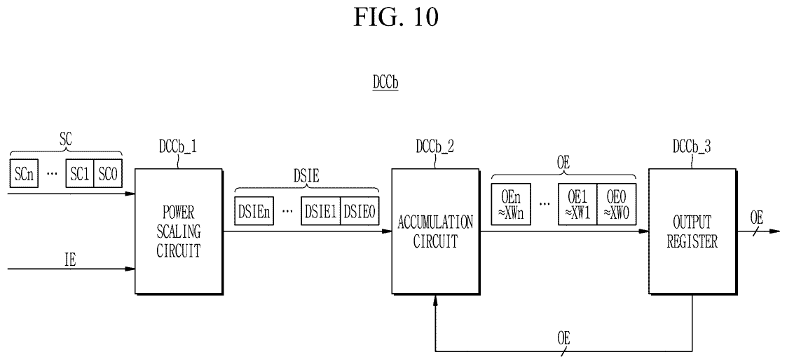

The input element scaling circuit DCCb may generate the plurality of output elements OE based on the input element IE and the plurality of scale coefficients SC. For example, the input element scaling circuit DCCb may generate 0-th to n-th output elements OE0-OEn based on the input element IE and the 0-th to n-th scale coefficients SC0-SCn. In this case, sizes (or amplitudes such as absolute values) of the 0-th to n-th output elements OE0-OEn may respectively correspond to values obtained by multiplying the 0-th to n-th weights W0-Wn by the input element IE. A configuration and an operation of the input element scaling circuit DCCb will be described in more detail with reference to FIG. 10 below.

In various example embodiments, the differential computation circuit DCC may further include a buffer circuit (not shown) configured to temporarily store the plurality of output elements OE and to provide the plurality of output elements OE to the memory cell array 130 collectively. However, example embodiments are not limited thereto.

FIG. 6 is a drawing showing an operation of the quantization circuit of FIG. 5 according to various example embodiments in more detail. Referring to FIGS. 1 to 6, the quantization circuit DCCa may generate the plurality of scale coefficients SC by quantizing the plurality of differential weights DW into a form of a power of 2. For a more concise description, hereinafter, various example embodiments in which the quantization circuit DCCa generates the 0-th to n-th scale coefficients SC0-SCn based on the 0-th to n-th differential weights DW0-DWn will be representatively described.

The quantization circuit DCCa may receive the 0-th to n-th differential weights DW0-DWn. The quantization circuit DCCa may convert a data type of each of the 0-th to n-th differential weights DW0-DWn to an integer data type to identify an amplitude (or a size or absolute value) of each of the 0-th to n-th differential weights DW0-DWn.

The quantization circuit DCCa may generate the 0-th to n-th scale coefficients SC0-SCn based on the amplitude of each of the 0-th to n-th differential weights DW0-DWn. For example, the quantization circuit DCCa may generate the 0-th to n-th scale coefficients SC0-SCn by quantizing amplitudes of the 0-th to n-th differential weights DW0-DWn respectively. For example, the quantization circuit DCCa may quantize the amplitude of each of the 0-th to n-th differential weights DW0-DWn in a form of 2N (wherein the N is an integer).

In some examples, the quantization circuit DCCa may approximate each of the 0-th to n-th differential weights DW0-DWn in a form of an integer power of 2 with an amplitude similar to an amplitude of each of the 0-th to n-th differential weights DW0-DWn. In this case, the quantization circuit DCCa may determine an exponent of each of the 0-th to n-th differential weights DW0-DWn approximated in the form of the integer power of 2 (i.e., N) as the 0-th to n-th scale coefficients SC0-SCn.

For a more detailed example, the quantization circuit DCCa may approximate an amplitude of the 0-th differential weight DW0 as 2^{N}^{₀}. In this case, the quantization circuit DCCa may determine the 0-th scale coefficient SC0 as N₀. Similarly, the quantization circuit DCCa may approximate an amplitude of the first differential weight DW1 as 2^{N}^{₁}. In this case, the quantization circuit DCCa may determine the first scale coefficient SC1 as N₁. In this way, the quantization circuit DCCa may determine the 0-th to n-th scale coefficients SC0-SCn.

In some cases, referring to FIG. 6, the quantization circuit DCCa may generate the 0-th to n-th scale coefficients SC0-SCn by quantizing all the 0-th to n-th differential weights DW1-DWn. In this case, data types of the 0-th to n-th scale coefficients SC0-SCn may be the same each other. However, example embodiments are not limited thereto.

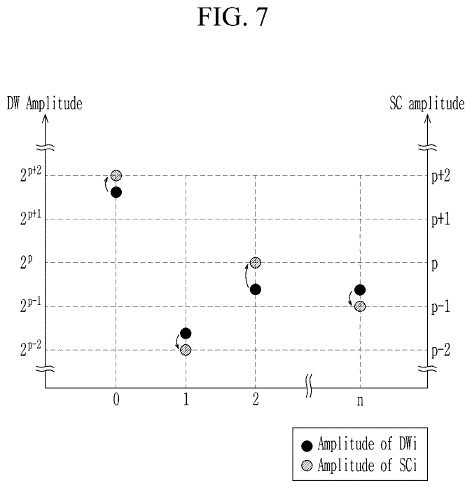

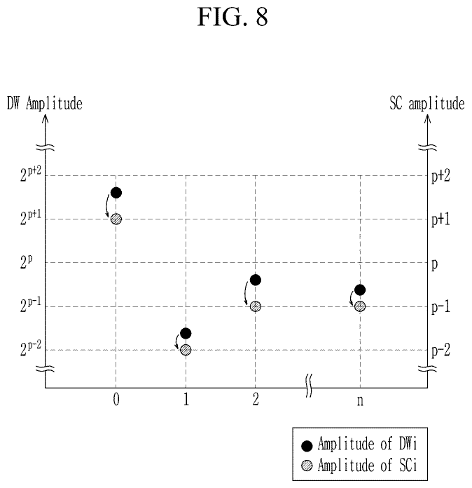

In various example embodiments, the quantization circuit DCCa may approximate the amplitude of each of the 0-th to n-th differential weights DW0-DWn in the form of the integer power of 2 based on various types of approximation algorithms such as rounding up, rounding down, rounding to nearest power of 2, and the like. A method in which the quantization circuit DCCa determines the 0-th to n-th scale coefficients SC0-SCn based on various types of approximation algorithms will be described in more detail with reference to FIG. 7 and FIG. 8 below.

FIG. 7 is a drawing showing an operation of the quantization circuit of FIG. 5 according to various example embodiments in more detail. A horizontal axis of FIG. 7 may represent indexes for the differential weight DW and the scale coefficient SC, and a vertical axis of FIG. 7 may represent amplitudes of the differential weight DW and the scale coefficient SC. Hereinafter, referring to FIGS. 1 to 7, an operation of the quantization circuit DCCa for respectively converting the 0-th to n-th differential weights DW0-DWn to the 0-th to n-th scale coefficients SC0-SCn based on the rounding to nearest power of 2 algorithm is representatively described.

The quantization circuit DCCa may identify the integer power of 2 having an amplitude most similar to an amplitude of each of the 0-th to n-th differential weights DW0-DWn. For example, the quantization circuit DCCa may identify that the integer power of 2 which has the most similar amplitude to the 0-th differential weight DW0 is 2^{p+2}. In this case, the quantization circuit DCCa may determine the 0-th scale coefficient SC0 corresponding to the 0-th differential weight DW0 as “p+2” that is an exponent of 2^{p+2}. Similarly, the quantization circuit DCCa may identify that the integer power of 2 which has the most similar amplitude to the first differential weight DW1 is 2^{p-2}; may identify that the integer power of 2 which has the most similar amplitude to the second differential weight DW2 is 2^{P}; and may identify that the integer power of 2 which has the most similar amplitude to the n-th differential weight DWn is 2^{p-1}. In this case, the quantization circuit DCCa may determine the first scale coefficient SC1 as “p−2”, may determine the second scale coefficient SC2 as “p”, and may determine the n-th scale coefficient SCn as “p−1”.

FIG. 8 is a drawing showing an operation of the quantization circuit of FIG. 5 according to various example embodiments in more detail. A horizontal axis of FIG. 8 may represent indexes for the differential weight DW and the scale coefficient SC, and a vertical axis of FIG. 8 may represent amplitudes of the differential weight DW and the scale coefficient SC. Hereinafter, referring to FIGS. 1 to 6 and 8, an operation of the quantization circuit DCCa for respectively converting the 0-th to n-th differential weights DW0-DWn to the 0-th to n-th scale coefficients SC0-SCn based on the rounding down approximation algorithm is representatively described.

The quantization circuit DCCa may identify the largest integer power of 2 among integer powers of 2 that are less than each of the 0-th to n-th differential weights DW0-DWn. For example, the quantization circuit DCCa may identify that the largest integer power of 2 which is less than the 0-th differential weight DW0 is 2^{p+1}. In this case, the quantization circuit DCCa may determine the 0-th scale coefficient SC0 corresponding to the 0-th differential weight DW0 as “p+1” that is an exponent of 2^{p+1}. Similarly, the quantization circuit DCCa may identify that the largest integer power of 2 which is less than the first differential weight DW1 is 2^{p-2}; may identify that the largest integer power of 2 which is less than the second differential weight DW2 is 2^{p-1}; and may identify that the largest integer power of 2 which is less than the n-th differential weight DWn is 2^{p-1}. In this case, the quantization circuit DCCa may determine the first scale coefficient SC1 as “p−2”, may determine the second scale coefficient SC2 as “p−1”, and may determine the n-th scale coefficient SCn as “p−1”.

FIG. 9 is a drawing showing an operation of the quantization circuit of FIG. 5 according to various example embodiments in more detail. Referring to FIGS. 1 to 5 and 9, the quantization circuit DCCa may generate the plurality of scale coefficients SC by quantizing the remaining differential weights except for the initial differential weight among the plurality of differential weights DW. For a more concise description, hereinafter, various example embodiments in which the quantization circuit DCCa generates the 0-th to n-th scale coefficients SC0-SCn based on the 0-th to n-th differential weights DW0-DWn will be representatively described.

The quantization circuit DCCa may not quantize the 0-th differential weight DW0. In this case, the 0-th scale coefficient SC0 may be equal to the 0-th differential weight DW0.

The quantization circuit DCCa may generate the first to n-th scale coefficients SC1-SCn by quantizing the first to n-th differential weights DW1-DWn. Because a method in which the quantization circuit DCCa generates the first to n-th scale coefficients SC1-SCn is similar to the methods described with reference to FIGS. 6 to 8, a detailed description thereof is omitted.

In some examples, the quantization circuit DCCa may not quantize only the initial differential weight among the 0-th to n-th differential weights DW0-DWn. In this case, the 0-th scale coefficient SC0 may have a different data type from those of the first to n-th scale coefficients SC1-SCn. For example, the 0-th scale coefficient SC0 may have a floating-point data type, and each of the first to n-th scale coefficients SC1-SCn may have an integer data type. In this case, because the 0-th differential weight DW0 is not quantized, an error of the output element OE that occurs due to quantization of the 0-th differential weight DW0 may be reduced or minimized.

FIG. 10 is a drawing showing a configuration and an operation of the input element scaling circuit of FIG. 5 in more detail. Referring to FIGS. 1 to 10, the input element scaling circuit DCCb may include a power scaling circuit DCCb_1, an accumulation circuit DCCb_2, and an output register DCCb_3.

The power scaling circuit DCCb_1 may receive the input element IE and the plurality of scale coefficients SC. For example, the power scaling circuit DCCb_1 may receive the input element IE, and may sequentially receive the 0-th to n-th scale coefficients SC0-SCn.

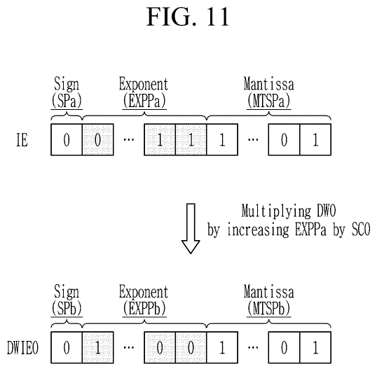

The power scaling circuit DCCb_1 may sequentially generate 0-th to n-th differentially scaled input elements DSIE0-DSIEn by multiplying the input element IE by each of powers of 2 for the 0-th to n-th scale coefficients SC0-SCn. For example, the power scaling circuit DCCb_1 may generate the 0-th differentially scaled input element DSIE0 by multiplying the input element IE with a power of 2 for the 0-th scale coefficient SC0; and may generate the first differentially scaled input element DSIE1 by multiplying the input element IE with a power of 2 for the first scale coefficient SC1. In this way, the power scaling circuit DCCb_1 may generate and sequentially output the 0-th to n-th differentially scaled input elements DSIE0-DSIEn. An operation of the power scaling circuit DCCb_1 will be described in more detail with reference to FIG. 11.

In various example embodiments, as described above with reference to FIG. 9, if the quantization circuit DCCa_1 is implemented as not to quantize the 0-th scale coefficient SC0, a data type of the 0-th scale coefficient SC0 may be a floating point. In this case, instead of multiplying the input element IE by the power of 2 for the 0-th scale coefficient SC0, the power scaling circuit DCCb_1 may generate the 0-th differentially scaled input element DSIE0 by performing floating point multiplication of the input element IE and the 0-th scale coefficient SC0. However, example embodiments are not limited thereto.

The accumulation circuit DCCb_2 may sequentially receive the plurality of differentially scaled input elements DSIE. The accumulation circuit DCCb_2 may sequentially provide the plurality of output elements OE to the output register DCCb_3 based on an order in which the plurality of differentially scaled input elements DSIE are provided. The output register DCCb_3 may sequentially provide the plurality of output elements OE to the input/output circuit 140 and the accumulation circuit DCCb_2.

For a more detailed example, the accumulation circuit DCCb_2 may generate the 0-th output element OE0 based on the 0-th differentially scaled input element DSIE0. The 0-th output element OE0 may be the same as the 0-th differentially scaled input element DSIE0. The accumulation circuit DCCb_2 may provide the 0-th output element OE0 to the output register DCCb_3. The output register DCCb_3 may provide the 0-th output element OE0 to the input/output circuit 140, and may feedback the 0-th output element OE0 to the accumulation circuit DCCb_2.

Thereafter, the accumulation circuit DCCb_2 may generate the first output element OE1 by accumulating the 0-th output element OE0 and the first differentially scaled input element DSIE1 provided from the output register DCCb_3. The accumulation circuit DCCb_2 may provide the first output element OE1 to the output register DCCb_3. The output register DCCb_3 may provide the first output element OE1 to the input/output circuit 140, and may feedback the first output element OE1 to the accumulation circuit DCCb_2.

In this way, the accumulation circuit DCCb_2 may generate the k-th output element OEk by accumulating the (k-1)-th output element OEk-1 and the k-th differentially scaled input element DSIEk provided from the output register DCCb_3, wherein the ‘k’ is an integer equal to or greater than 1 and equal to or less than n. In this case, the accumulation circuit DCCb_2 may provide the k-th output element OEk to the output register DCCb_3, and the output register DCCb_3 may provide the k-th output element OEk to the host device 10 through the input/output circuit 140.

In other words, the accumulation circuit DCCb_2 may generate the plurality of output elements OE by sequentially accumulating the plurality of differentially scaled input elements DSIE. In this case, the 0-th output element OE0 may be the same as the 0-th differentially scaled input element DSIE0; and the k-th output element OEk may correspond to a sum of the 0-th to k-th differentially scaled input elements DSIE0-DSIEk.

On the other hand, powers of 2 for the 0-th to n-th scale coefficients SC0-SCn may be approximate values of the 0-th to n-th differential weights DW0-DWn, respectively. In this case, the 0-th to k-th differentially scaled input elements DSIE0-DSIEk may be approximated values for products of the 0-th to n-th differential weights DW0-DWn and the input element IE, respectively. That is, the 0-th differentially scaled input element DSIE0 may be the approximated value for the product of the input element IE and the 0-th differential weight DW0; and the k-th differentially scaled input elements DSIEk may be the approximated value for the product of the input element IE and the k-th differential weight DWk.

Accordingly, the k-th output element OEk corresponding to the sum of the 0-th to k-th differentially scaled input elements DSIE0-DSIEk may be an approximate value of a value obtained by multiplying the input element IE by a sum of the 0-th to k-th differential weights DW0-DWk. In this case, the sum of the 0-th to k-th differential weights DW0-DWk may correspond to the k-th weight Wk, so that the k-th output element OEk may be a product of the k-th weight Wk and the input element IE. In this way, the differential computation circuit DCC may compute the plurality of output elements OE corresponding to products of the input element IE and the plurality of weights W.

As a result, according to some example embodiments, the differential computation circuit DCC may perform the product of the input element IE and each of the plurality of weights W with a smaller amount of computation. For example, according to some example embodiments, the differential computation circuit DCC may compute the plurality of output elements OE corresponding to the products of the plurality of weights W and the input elements IE even if it does not perform floating-point multiplication on the plurality of weights W and the input element IE.

FIG. 11 is a drawing showing an operation of the power scaling circuit of FIG. 10 in more detail. Referring to FIGS. 1 to 8, 10, and 11, the power scaling circuit DCCb_1 may sequentially generate the 0-th to n-th differentially scaled input elements DSIE0-DSIEn by multiplying the input element IE with each of powers of 2 for the 0-th to n-th scale coefficients SC0-SCn. For a more concise description, hereinafter, an operation of the power scaling circuit DCCb_1 for generating the 0-th differentially scaled input element DSIE0 will be representatively described. However, example embodiments are not limited thereto, and in a similar manner, the power scaling circuit DCCb_1 may also generate the first to n-th differentially scaled input elements DSIE1-DSIEn.

The input element IE may have a floating-point data type. For example, the input element IE may include a sign part SPa, an exponent part EXPPa, and a mantissa part MTSPa.

The power scaling circuit DCCb_1 may generate the 0-th differentially scaled input element DSIE0 by changing the exponent part EXPPa based on the 0-th scale coefficient SC0. For example, the power scaling circuit DCCb_1 may generates the 0-th differentially scaled input element DSIE0 corresponding to a result of multiplying the input element IE by the power of 2 for the 0-th scale coefficient SC0 by increasing the exponent part EXPPa as the 0-th scale coefficient SC0.

The 0-th differentially scaled input element DSIE0 may have a floating-point data type. For example, the 0-th differentially scaled input element DSIE0 may include a sign part SPb, an exponent part EXPPb, and a mantissa part MTSPb. In this case, the sign part SPb may be the same as the sign part SPa, and the mantissa part MTSPb may be the same as the mantissa part MTSPa. The exponent part EXPPb may be larger than the exponent part EXPPa by the 0-th scale coefficient SC0.

For example, according to some example embodiments, the power scaling circuit DCCb_1 may generate the plurality of differentially scaled input elements DSIE by only changing the exponent part EXPPa of the input element IE. In this case, because the input element IE is scaled by increasing the exponent part EXPPa without performing floating point multiplication, the differential computation circuit DCC may be implemented with a smaller number of transistors. Therefore, according to some example embodiments, a circuit area, consumption power, and an amount of computation of the differential computation circuit DCC may be reduced or minimized.

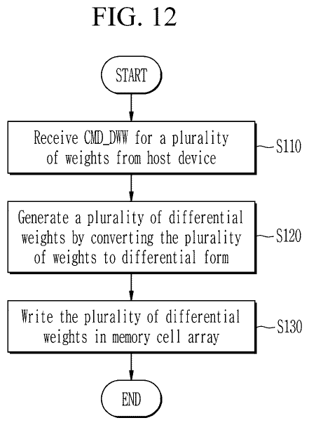

FIG. 12 is a flowchart showing an operation method of the memory device according to various example embodiments of the present disclosure. Referring to FIGS. 1 to 12, in operation S110, the memory device 100 may receive the differential weight write command CMD_DWW for the plurality of weights W from the host device 10.

In operation S120, the memory device 100 may generate the plurality of differential weights DW by converting the plurality of weights W to the differential format. For example, the internal processor 111 may generate the 0-th to n-th differential weights DW0-DWn based on the 0-th to n-th weights W0-Wn.

In operation S130, the memory device 100 may write the plurality of differential weights DW in the memory cell array 130. For example, the control logic circuit 110 may control the row decoder 120 and the input/output circuit 140 to store the 0-th to n-th differential weights DW0-DWn in the memory cell array 130.

For a more concise description, the embodiment in which the operation S130 is performed after the operation S120 is representatively described in FIG. 12, but example embodiments are not limited thereto. For example, the memory device 100 may be implemented to repeatedly perform an operation of generating one differential weight DW and storing the one differential weight DW in the memory cell array 130.

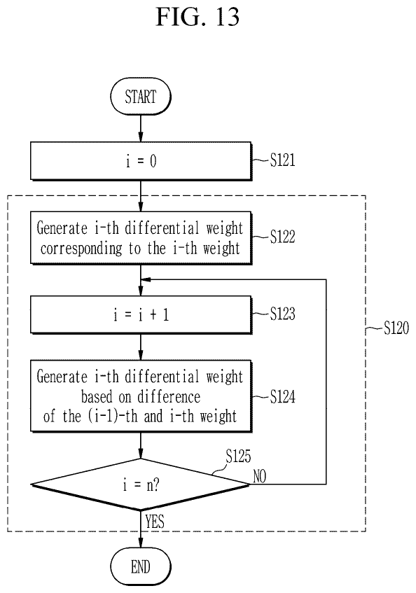

FIG. 13 is a flowchart showing the operation S120 of FIG. 12 in more detail. Referring to FIGS. 1 to 13, the operation S120 may include the following steps S121 to S125.

In the operation S121, a variable i may be set to 0. The variable i is only used to describe a repetitive operation of the format conversion circuit FCC, but example embodiments are not limited thereto.

In the operation S122, the format conversion circuit FCC may generate the i-th differential weight DWi corresponding to the i-th weight Wi. That is, the format conversion circuit FCC may generate the 0-th differential weight DW0 corresponding to the 0-th weight W0. In this case, the 0-th differential weight DW0 may be equal to the 0-th weight W0.

In the operation S123, the format conversion circuit FCC may increase the variable i by “1”.

In the operation S124, the format conversion circuit FCC may generate the i-th differential weight DWi based on a difference between the (i-1)-th Wi-1 and the i-th weight Wi. For example, the format conversion circuit FCC may generate the i-th differential weight DWi based on a value obtained by subtracting the (i-1)-th weight Wi-1 from the i-th weight Wi.

In the operation S125, the format conversion circuit FCC may determine whether the variable i is “n”. For example, the format conversion circuit FCC may determine whether the differential weight DW is generated for all weights W. If the variable i is determined to be “n”, the operation S120 may be terminated, and if the variable i is determined not to be “n”, the operation S123 described above may be repeatedly performed. In this way, the format conversion circuit FCC may sequentially generate the 0-th to n-th differential weights DW0-DWn.

In various example embodiments, if the memory device 100 is implemented to repeatedly perform generating one differential weight DW and storing the one differential weight DW in the memory cell array 130, the control logic circuit 110 may be implemented to store the differential weight DW generated after the operations S122 and S124 are performed in the memory cell array 130. However, example embodiments are not limited thereto.

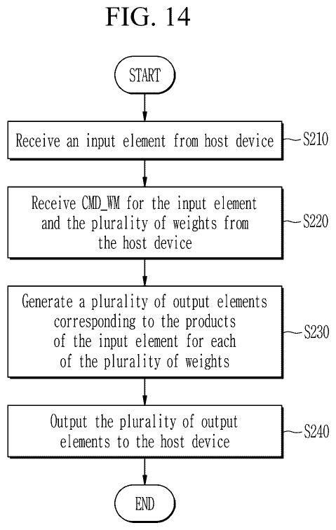

FIG. 14 is a flowchart showing an operation method of the memory device according to various example embodiments of the present disclosure. Referring to FIGS. 1 to 14, in operation S210, the memory device 100 may receive the input element IE from the host device 10. In this case, the memory device 100 may store the input element IE in the memory cell array 130.

For a more concise description, hereinafter, it is assumed that the above-described steps S110 to S130 has been performed before operation S220 is performed. In this case, before the operation S220 is performed, the input element IE and the plurality of differential weights DW may be stored in the memory cell array 130.

In the operation S220, the memory device 100 may receive the weight multiplication command CMD_WM for the input element IE and the plurality of differential weights DW from the host device 10.

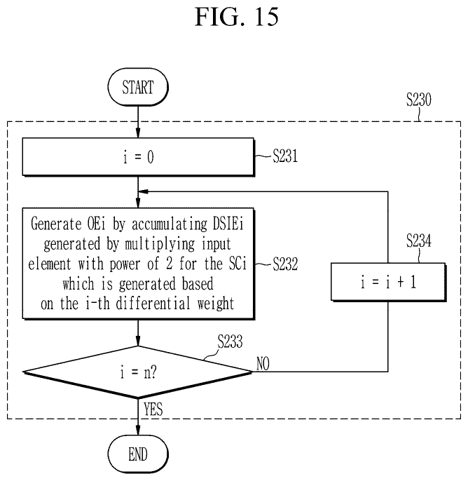

In operation S230, the memory device 100 may generate the plurality of output elements OE corresponding to the products of the input element IE and the plurality of differential weights DW. For example, the internal processor 111 may generate the 0-th to n-th output elements OE0-OEn based on the input element IE and the 0-th to n-th differential weights DW0-DWn. The operation S230 will be described in more detail with reference to FIG. 15 below.

In operation S240, the memory device 100 may output the plurality of output elements OE to the host device 10. For example, the memory device 100 may output the 0-th to n-th output elements OE0-OEn to the host device 10.

For a more concise description, the embodiment in which the operation S240 is performed after the operation S230 is representatively described in FIG. 14, but example embodiments are not limited thereto. For example, the memory device 100 may be implemented to repeatedly perform an operation of generating one output element OE and outputting the one output element OE to the host device 10.

FIG. 15 is a flowchart showing the operation S230 of FIG. 14 in more detail. Referring to FIGS. 1 to 15, the operation S230 may include the following steps S231 to S234.

In the operation S231, a variable i may be set to 0. The variable i is only used to describe a repetitive operation of the differential computation circuit DCC, but example embodiments are not limited thereto.

In the operation S232, the differential computation circuit DCC may to generate the i-th output element OEi by accumulating the i-th differentially scaled input element DSIEi which is generated by multiplying the input element IE with a power of 2 for the i-th scale coefficient SCi generated based on the i-th differential weight DWi. For example, the quantization circuit DCCa may generate the i-th scale coefficient SCi based on the i-th differential weight DWi; and the input element scaling circuit DCCb may generate the i-th output element OEi by accumulating the i-th differentially scaled input element DSIEi generated based on the i-th scale coefficient SCi and the input element IE.

For a more detailed example, the power scaling circuit DCCb_1 may generate the i-th differentially scaled input element DSIEi by multiplying the input element IE by the power of 2 for the i-th scale coefficient SCi. The accumulation circuit DCCb_2 may generate the i-th output element OEi by accumulating the 0-th to i-th differentially scaled input elements DSIE0-DSIEi.

In operation S233, the differential computation circuit DCC may determine whether the variable i is “n”. For example, the differential computation circuit DCC may determine whether the output elements OE corresponding to all weights W has been generated. If the variable i is determined to be “n”, the operation S230 may be terminated, and if the variable i is determined not to be “n”, the following operation S234 may be performed.

In the operation S234, the differential computation circuit DCC may increase the variable i by “1”. Thereafter, the operation S232 described above may be repeatedly performed. In this way, the differential computation circuit DCC may sequentially generate the 0-th to n-th output elements OE0-OEn.

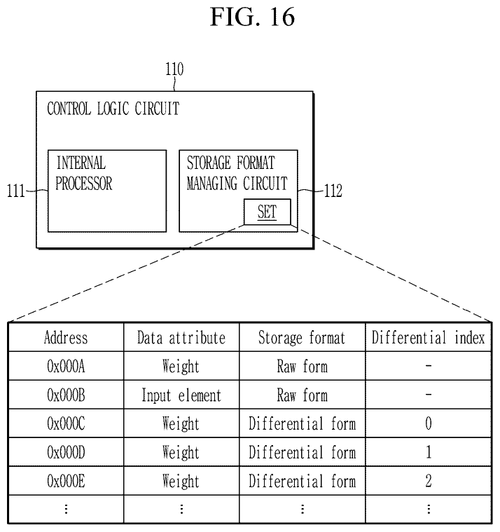

FIG. 16 is a drawing showing a configuration and an operation of the control logic circuit of FIG. 2 according to various example embodiments. Referring to FIGS. 1 to 16, the control logic circuit 110 may include the internal processor 111 and a storage format managing circuit 112. Detailed descriptions of a configuration and an operation of the internal processor 111 described above with reference to FIG. 2 will be omitted.

The storage format managing circuit 112 may include a storage format table SFT. The storage format managing circuit 112 may manage input/output operations of the memory device 100 based on the storage format table SFT.

The storage format managing circuit 112 may manage a format of data stored in the memory cell array 130 based on the storage format table SFT. For example, the storage format table SFT may indicate one or more of an address, a data attribute, a storage format, and a differential index of the memory cell array 130.

For a more detailed example, the storage format table SFT may indicate that the weight W is stored in a raw format in the address “0x000A” of the memory cell array 130; may indicate that the input element IE is stored in a raw format in the address “0x000B” of the memory cell array 130; and may indicate that the plurality of weights W are stored in differential forms in addresses “0x000C to 0x000E” of the memory cell array 130. In some examples, the storage format table SFT may indicate that the data stored in the addresses “0x000C to 0x000E” are the differential weight DW.

The storage format managing circuit 112 may perform a read operation in response to a read command from the host device 10 based on the storage format table SFT.

If a read command for the data stored in the raw format is issued from the host device 10, the storage format managing circuit 112 may control the memory device 100 to perform a normal (e.g., conventional) read operation on the data stored in the raw format. For a more detailed example, if a read command for the address “0x000A” is issued from the host device 10, the storage format managing circuit 112 may control the memory device 100 to output data stored in the address “0x000A” to the host device 10.

On the other hand, if a read command for the data stored in the differential format is issued from the host device 10, the storage format managing circuit 112 may convert the data stored in the differential format into a raw format and then provide the converted data to the host device 10. For a more detailed example, if a read command for the address “0x000E” is issued from the host device 10, the storage format managing circuit 112 may identify that the data stored in the address “0x000E” is the second differential weight DW2 based on the differential index value ‘2’. In this case, the storage format managing circuit 112 may control the internal processor 111 to compute the second weight W2 by summing the data (i.e., the 0-th and first differential weights DW0 and DW1) stored in the addresses (i.e., 0x000C and 0x000D) corresponding to the differential indexes 0 and 1, and the second differential weight DW2. Thereafter, the storage format managing circuit 112 may control the memory device 100 to output the computed second weight W2 to the host device 10.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

The contents described above are specific embodiments for implementing the present disclosure. Examples may include not only the above-described example embodiments but also example embodiments that may be simply changed in design and/or may be easily modified. Additionally, example embodiments may also include technologies that may be easily modified and implemented using the embodiments. Therefore, the scope of the present disclosure should not be limited to the above-described embodiments, but should be defined by the claims described below as well as the claims and equivalents of the present disclosure. Further, example embodiments are not necessarily mutually exclusive. For example, some example embodiments may include one or more features described with reference to one or more figures, and may also include one or more other features described with reference to one or more other figures.

What is claimed is:

1. A memory device comprising:
a format conversion circuit configured to generate a plurality of differential weights based on a plurality of weights provided from an external device;
a memory cell array configured to store a first input element provided from the external device and to store the plurality of differential weights;
a quantization circuit configured to generate a plurality of scale coefficients based on the plurality of differential weights; and
an input element scaling circuit configured to provide a plurality of output elements corresponding to products of the first input element with each of the plurality of weights to the external device based on the plurality of scale coefficients.

2. The memory device of claim 1, wherein the format conversion circuit is configured to generate a first differential weight included in the plurality of differential weights based on a difference between a first weight and a second weight included in the plurality of weights.

3. The memory device of claim 1, wherein powers of 2 for the plurality of scale coefficients respectively correspond to amplitudes of the plurality of differential weights.

4. The memory device of claim 1, wherein:
each of the first input element, the plurality of weights, and the plurality of differential weights has a floating-point data type, and
each of the plurality of scale coefficients has an integer data type.

5. The memory device of claim 4, wherein the input element scaling circuit comprises:
a power scaling circuit configured to generate a plurality of differentially scaled input elements corresponding to products of the first input element with each of the plurality of differential weights based on the plurality of scale coefficients; and
an accumulation circuit configured to generate the plurality of output elements by sequentially accumulating the plurality of differentially scaled input elements.

6. The memory device of claim 5, wherein the input element scaling circuit further comprises:
an output register configured to sequentially receive the plurality of output elements and to sequentially provide the plurality of output elements to the external device and the accumulation circuit.

7. The memory device of claim 5, wherein the power scaling circuit is configured to generate the plurality of differentially scaled input elements by changing an exponent part of the first input element based on the plurality of scale coefficients.

8. The memory device of claim 1, further comprising:
a storage format managing circuit configured to manage a storage format table indicating storage formats of the plurality of differential weights.

9. A differential computation circuit included in an internal processor of a memory device, comprising:
a quantization circuit configured to generate 0-th to n-th scale coefficients based on 0-th to n-th differential weights (wherein n is an integer greater than or equal to 1); and
an input element scaling circuit configured to generate 0-th to n-th output elements based on the 0-th to n-th scale coefficients and an input element,
wherein the input element scaling circuit comprises,
a power scaling circuit configured to generate 0-th to n-th differentially scaled input elements by scaling the input element based on the 0-th to n-th scale coefficients, and
an accumulation circuit configured to sequentially generate the 0-th to n-th output elements by sequentially accumulating the 0-th to n-th differentially scaled input elements.

10. The differential computation circuit of claim 9, wherein powers of 2 for the first to n-th scale coefficients correspond to amplitudes of the first to n-th differential weights respectively.

11. The differential computation circuit of claim 10, wherein the 0-th scale coefficient and the 0-th differential weight are same as each other.

12. The differential computation circuit of claim 11, wherein,
a data type of each of the first to n-th scale coefficients is a first data type, and
a data type of the 0-th scale coefficient is a second data type different from the first data type.

13. The differential computation circuit of claim 10, wherein the quantization circuit is configured to:
approximate an amplitude of each of the 0-th to n-th scale coefficients in a form of a power of 2; and
generate the 0-th to n-th scale coefficients respectively based on exponent parts of the 0-th to n-th scale coefficients approximated in the form of the power of 2.

14. The differential computation circuit of claim 10, wherein the power scaling circuit is configured to:
generate a k-th differentially scaled input element by changing an exponent part of the input element by a k-th scale coefficient (wherein k is an integer greater than or equal to 1 and less than or equal to n).

15. The differential computation circuit of claim 9, wherein a k-th output element among the 0-th to n-th output elements corresponds to a total sum of the 0-th to k-th differentially scaled input elements.

16. The differential computation circuit of claim 14, wherein the input element scaling circuit further comprises:
an output register configured to sequentially receive the 0-th to n-th output elements and to sequentially provide the 0-th to n-th output elements to an external device and the accumulation circuit.

17. The differential computation circuit of claim 16, wherein the accumulation circuit is configured to:
generate the k-th output element by accumulating a (k-1)-th differentially scaled input element provided from the power scaling circuit with a (k-1)-th output element provided from the output register.

18. An operation method of a memory device, comprising:
storing 0-th and first differential weights generated based on 0-th and first weights provided from an external device;
receiving a first input element from the external device;
receiving a weight multiplication command for the 0-th and first weights and the first input element from the external device;
generating, based on 0-th and first differentially scaled input elements respectively corresponding to products of the first input element with the 0-th and first differential weights, 0-th and first output elements respectively corresponding to products of the first input element with the 0-th and first weights, in response to the weight multiplication command; and
outputting the 0-th and first output elements to the external device.

19. The operation method of claim 18, wherein the storing comprises:
generating the 0-th differential weight based on the 0-th weight; and
generating the first differential weight based on a difference between the first weight and the 0-th weight.

20. The operation method of claim 18, wherein the generating comprises:
generating a 0-th scale coefficient based on the 0-th differential weight;
generating a 0-th differentially scaled input element corresponding to the 0-th output element based on the 0-th scale coefficient and the first input element;
generating a first scale coefficient based on the first differential weight;
generating a first differentially scaled input element based on the first scale coefficient and the first input element; and
generating the first output element by accumulating the first output element and the first differentially scaled input element.
